(19) United States
(12) Patent Application Publication
(10) Pub. No.: US 2026/0074587 A1
(43) Pub. Date: Mar. 12, 2026

(54) POWER COUPLING DEVICES FOR HIGH-TEMPERATURE SUPERCONDUCTORS

(71) Applicant: Microsoft Technology Licensing, LLC, Redmond, WA (US)

(72) Inventors: Ruslan NAGIMOV, Snohomish, WA (US); Winston Allen SAUNDERS, Seattle, WA (US)

(73) Assignee: Microsoft Technology Licensing, LLC, Redmond, WA (US)

(21) Appl. No.: 18/806,380

(22) Filed: Aug. 15, 2024

(51) Int. Cl. H02K 7/18; H02K 7/00; H05K 7/14

(52) U.S. Cl. CPC H02K 7/1807; H02K 7/003; H05K 7/1485

(57) ABSTRACT

According to examples, a thermally separating power coupling device includes a housing that thermally and electrically isolates a high-temperature superconductor (HTS) from an electrically conductive cable. The power coupling device includes a power coupling system that includes a rotatable shaft having a motor side and a generator side. On the motor side, a set of motor magnets is attached to the shaft and a set of motor coils are positioned near the set of motor magnets. On the generator side, a set of generator magnets is attached to the shaft and a set of generator coils is positioned near the generator coils. When electrical current is supplied from the HTS to the motor coils, the motor coils rotate, thus causing the shaft to rotate. In addition, as the shaft rotates, the generator coils produce an electrical current that is outputted to the electrically conductive cable.

### BACKGROUND

Computing equipment, essential for various aspects of modern life—including business systems, commerce applications, and artificial intelligence—are commonly housed in data centers, also known as server farms. These data centers accommodate a range of computing devices that include processors such as central processing units (CPUs) and graphics processing units (GPUs). Additionally, data centers host other computing equipment such as network switches and power supplies, to name a few. The computing equipment is often organized into racks, with many data centers housing hundreds or even thousands of these racks. As computational demands continue to rise, data centers are increasing the density of equipment within each rack. Consequently, the growing number of computing devices has led to higher power demands in the racks housed in the data centers.

### BRIEF DESCRIPTION OF DRAWINGS

Features of the present disclosure are illustrated by way of examples shown in the following figures. In the following figures, like numerals indicate like elements, in which:

FIG. 1 shows a block diagram of a data center that houses power coupling devices that thermally separate respective high temperature superconductors (HTSs) from electrically conductive cables to deliver power to electronic equipment, in accordance with an embodiment of the present disclosure;

FIG. 2 shows a cross-sectional side view of a portion of a power connection system shown in FIG. 1, in accordance with an embodiment of the present disclosure;

FIGS. 3A and 3B, respectively, depict enlarged views of the power coupling device depicted in FIG. 2, in accordance with embodiments of the present disclosure;

FIGS. 4A and 4B, respectively, show isometric side views of the shaft shown in

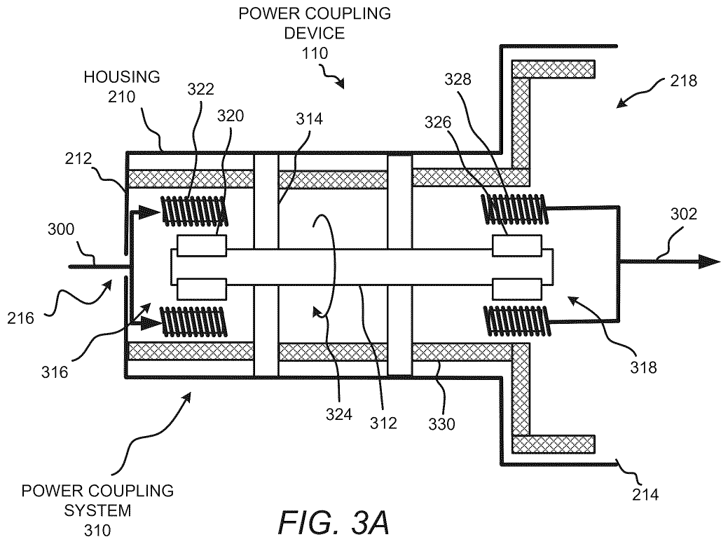

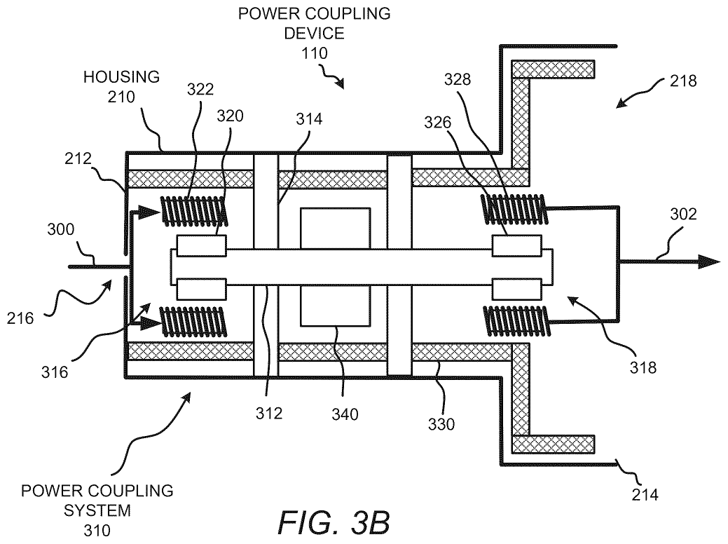

FIGS. 3A and 3B, in accordance with embodiments of the present disclosure; and

FIGS. 5A and 5B, respectively, show diagrams of an output current frequency control system, in accordance with embodiments of the present disclosure.

### DETAILED DESCRIPTION

For simplicity and illustrative purposes, the principles of the present disclosure are described by referring mainly to embodiments and examples thereof. In the following description, numerous specific details are set forth in order to provide an understanding of the embodiments and examples. It will be apparent, however, to one of ordinary skill in the art, that the embodiments and examples may be practiced without limitation to these specific details. In some instances, well-known methods and/or structures have not been described in detail so as not to unnecessarily obscure the description of the embodiments and examples. Furthermore, the embodiments and examples may be used together in various combinations.

Throughout the present disclosure, the terms “a” and “an” are intended to denote at least one of a particular element. As used herein, the term “includes” means includes but not limited to, the term “including” means including but not limited to.

Data centers are being designed and constructed to house ever growing numbers of power consuming devices. For instance, the latest artificial intelligence (AI) data center designs include ever increasing graphics processing unit (GPU) deployment densities. This is due in part to the fact that distributed model training workloads are synchronous and sensitive to network latencies. To reduce the network latency, the GPUs are deployed as densely as possible and are positioned as close to each other and to network switches as possible, which densifies the arrangement of GPUs in racks. This results in data center and rack designs that have extremely high power densities, for instance, an order of magnitude greater than racks that house conventional servers. Delivering that much power is challenging because current in power cables must be significantly increased to meet safety limitations placed on voltage levels. However, to increase current to such levels, the cross-section size of conventional cables, such as copper cables, must be significantly increased. As the power requirements continue to increase, the cross-section size of the cables become so large as to impede the increase of GPU deployment densities.

Disclosed herein are power coupling devices that enable the use of high-temperature superconductors (HTSs) to supply power to components in a data center while thermally and electrically isolating the HTSs from copper cables. The HTSs have significantly smaller cross-sectional sizes than conventional electrically conductive cables that are able to conduct similar levels of current and thus, the power coupling devices disclosed herein enable for the continued increase in GPU densities in data centers.

As disclosed herein, the power coupling device “air-gaps” cold HTS conductors from warm electrical conductors via a magnetically coupled rotating shaft. Particularly, energy transfer from the cold HTS conductors to the warm electrical conductors occurs mechanically via an alternating current (AC) motor, brushless electronically communicated motor, or other type of electric motors on one side of the power coupling device and an electric generator on the other side of the power coupling device. In some examples, the rotating shaft is housed inside of a vacuum jacketed space within the power coupling device, which ensures thermal insulation and reduced friction during rotation of the shaft. In addition, the shaft is made of a low thermal conductivity material to ensure low thermal transfer from the cold side of the power coupling device to the warm side of the power coupling device.

According to examples, the AC frequency of the input and output power feeds are independently adjustable. The AC frequency of the output power feed is adjustable, for instance, by changing the number of magnet poles included in the AC generator. In addition or alternatively, the AC frequency of the input power feed is adjustable, for instance, through use of a motor controller or a variable frequency drive. By adjusting the AC frequency of the output power feed as disclosed herein, higher density power supply units and power conversion devices may be employed.

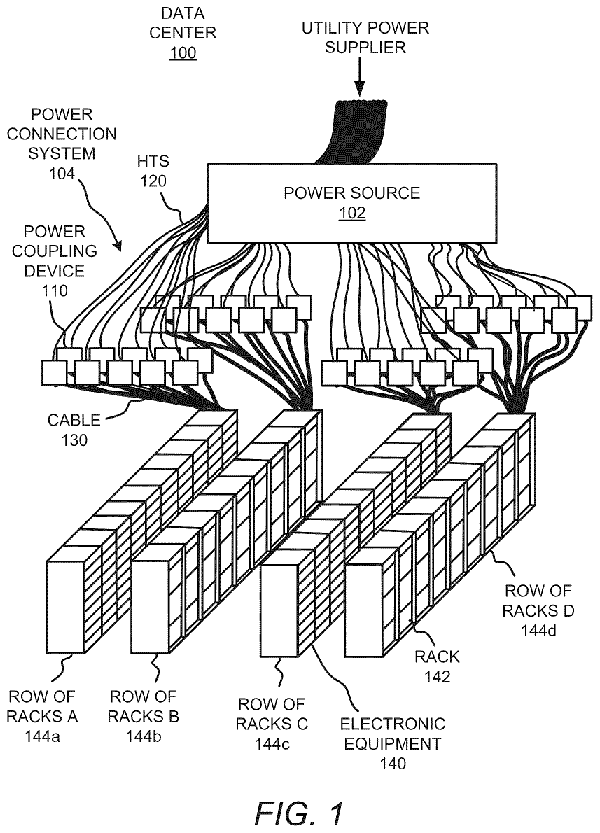

Reference is first made to FIG. 1, which shows a block diagram of a data center 100 that houses power coupling devices 110 that thermally separate respective high temperature superconductors (HTSs) 120 from electrically conductive cables 130 to deliver power to electronic equipment 140, in accordance with an embodiment of the present disclosure. It should be understood that the data center 100 shown in FIG. 1 may include additional elements and that some of the elements described herein may be removed and/or modified without departing from the scope of the present disclosure. For instance, the data center 100 may include any number of electronic equipment 140, racks 142, rows of racks 144a-144d, and various other components. It should thus be understood that the number and arrangements of components depicted in FIG. 1 are for illustrative purposes and are thus not intended to limit the scope of the present disclosure.

As shown in FIG. 1, a number of electronic equipment 140 are housed within a number of racks 142 that are arranged in rows of racks 144a-144d such that, for instance, the front sides of the electronic equipment 140 in adjacent rows of racks 144a-144d face each other and the rear sides of the electronic equipment 140 in other rows of racks 144a-144d face each other. In some instances, the aisles between the rows of racks 144a-144d in which the front sides of the electronic equipment 140 face each other are cool aisles and the aisles between the rows of racks 144a-144d in which the rear sides of the electronic equipment 140 face each other are hot aisles. In these instances, cooling airflow is provided to the electronic equipment 140 through the cool aisles and airflow that has been heated by the electronic equipment 140 is expelled through the hot aisles. In other instances, some or all of the electronic equipment 140 are cooled through other techniques, such as through liquid or refrigerant cooling.

The electronic equipment 140 include any type of equipment typically found in data centers. For instance, the electronic equipment 140 include servers, storage devices, networking devices (such as routers, switches, etc.), power management equipment, etc. By way of particular example, some or all of the electronic equipment 140 are systems that include multiple graphical processing units (GPUs) that are densely packed together as may be used in artificial intelligence (AI) applications. The AI applications may include, for instance, the training of deep learning models, scientific simulations, high resolution video rendering, and/or the like.

Distributed model training workloads on large numbers of GPUs are synchronous and sensitive to network latencies. To reduce or minimize network latencies and to maximize processing performance, the GPUs are deployed as densely as possible within the racks 142, and the GPUs are positioned within certain distances from main network switches. As a result, racks 142 housing relatively large numbers of GPUs require extremely high power densities, which, in some instances, are an order of magnitude greater than racks 142 that house servers with CPUs and lesser numbers of GPUs. By way of example, each of the racks 142 may require around 1 MW of power. In order to deliver 1 MW of power, current in the power cables should be around 1000 A, for instance, to meet safety limitations placed on voltage levels.

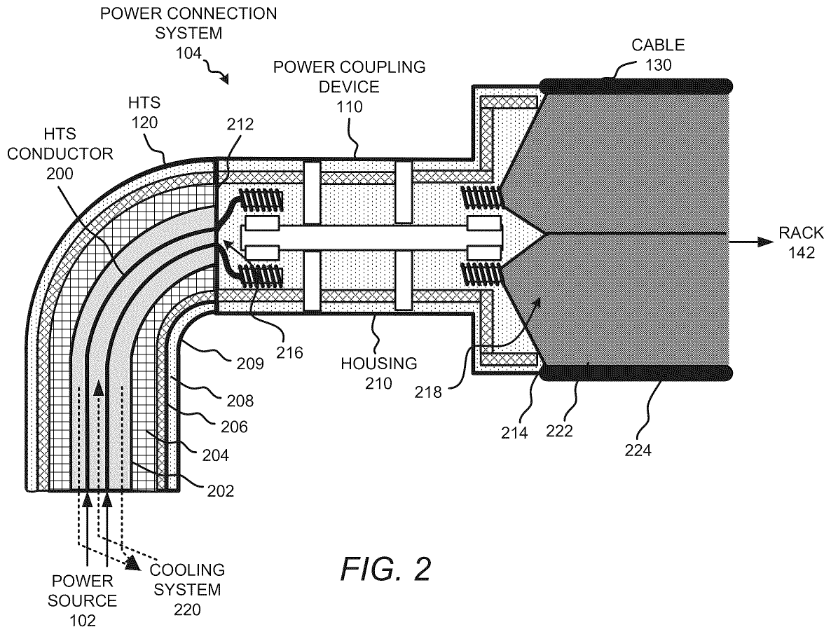

According to examples, the electrically conductive cables 130 are able to deliver the same or approximately the same amount of current as the HTSs 120. In order to deliver that amount of current, due to losses in the electrically conductive cables 130, the electrically conductive cables 130 have relatively larger cross-sections than the HTSs 120. For instance, the electrically conductive cables 130 have cross-sectional diameters that are approximately 10 times larger than the cross-sectional diameters of the HTSs 120. However, because the HTSs 120 operate at very low temperatures, e.g., cryogenic temperatures, it is undesirable to connect the HTSs 120 directly to the racks 142. For instance, the very low temperatures may cause condensation to occur near the electronic equipment 140 in the racks 142 which may negatively affect their performance and may cause damage to the electronic equipment 140. In addition, direct coupling of HTSs 120 to warm components may increase the heat inleaks into the HTS conductors 200 (FIG. 2) and increase the refrigeration load on the cryogenic system.

As shown in FIG. 1, a power source 102 distributes power received from a utility power supplier to the electronic equipment 140 in the data center 100 through power connection systems 104. The power connection systems 104 include respective sets of HTSs 120, power coupling devices 110, and electrically conductive cables 130. For instance, there may be a connection for the HTSs 120 of the power connection systems 104 to provide power to each of the racks 142 in the data center 100. It should be understood that the ends of the electrically conductive cables 130 are shown as being connected to particular ones of the racks 142 for purposes of illustration and thus, the electrically conductive cables 130 may instead terminate at respective ones of the racks 142.

As discussed in greater detail herein, the power coupling devices 110 thermally separate the electrically conductive cables 130 from the HTSs 120. That is, the power coupling devices 110 function as thermal insulators between the HTSs 120 and the electrically conductive cables 130 to which they are connected. However, the power coupling devices 110 enable electrical current supplied into the power coupling device 110 through the HTSs 120 to be converted and for the converted electrical current to be outputted through the electrically conductive cables 130 and to the electronic equipment 140 in the racks 142.

In the example data center 100 depicted in FIG. 1, forty racks 142 arranged in four rows of racks 144a-144d are shown for purposes of illustration. However, it should be understood that the data center 100 may have hundreds if not thousands of racks 142 and thus, there may be hundreds or even thousands of power connection systems 104 between the power source 102 and the racks 142. The power connection systems 104 themselves thus occupy a significantly large amount of space in the data center 100.

As discussed herein, in order to deliver equivalent amounts of power or current, the electrically conductive cables 130 have much larger cross-sectional diameters than the HTSs 120. According to examples, the amount of space occupied by the cables that deliver power to the electronic equipment 140 from the power source 102 is thus reduced through the use of high-temperature superconductors (HTSs) 120 and electrically conductive cables 130 that are coupled to each other through thermally separating power coupling devices 110 as discussed herein. In other words, the lengths of the electrically conductive cables 130 may be shortened, which reduces the space occupied by the power connection systems 104 as compared to use of only the electrically conductive cables 130. One result of reducing the spaced occupied by the power cables is that GPUs may be deployed at substantially higher densities, thus enabling greater distributed model training workloads to be executed.

The HTSs 120 include respective HTS conductors 200 (FIG. 2) that run through the HTSs 120, in which the HTS conductors 200 are formed of a material that has a critical temperature, e.g., the temperature below which the material behaves as a superconductor, above a certain temperature. For instance, the certain temperature is the boiling point of liquid nitrogen, which is around 77K (−192.2° C.). In other words, the HTS conductors 200 conduct electricity with minimal resistance or without resistance when the HTS conductors 200 are below the critical temperature. The HTSs 120 also include channels for a cooling liquid to be provided around the HTS conductors 200 to cool the HTS conductors 200 to the certain temperature as discussed herein.

The electrically conductive cables 130 are any suitable type of electrically conductive cable that is to conduct electricity at normal operating temperatures of data centers. The normal operating temperatures of data centers may be between about 18° C. to about 40° C. In addition, the electrically conductive cables 130 have sufficiently sized cross-sections to safely handle delivery of electrical current to sufficiently power the electronic equipment 140 in a rack 142. By way of particular example, the electrically conductive cables 130 have sufficiently large cross-sections to safely handle delivery of around 1 MW of power to the electronic equipment 140 in a rack 142 at the normal operating temperatures. The electrically conductive cables 130 may include copper cables, aluminum cables, or the like.

FIG. 2 shows a cross-sectional side view of a portion of a power connection system 104 shown in FIG. 1, in accordance with an embodiment of the present disclosure. It should be understood that the power connection system 104 shown in FIG. 2 may include additional elements and that some of the elements described herein may be removed and/or modified without departing from the scope of the present disclosure.

As shown in FIG. 2, the power connection system 104 includes an HTS 120, a power coupling device 110, and an electrically conductive cable 130 (which is also referenced herein as a cable 130). The power coupling device 110 (which is also referenced herein as a thermally separating power coupling device 110) includes a housing 210. The housing 210 is shown as including a first end 212 at which the HTS 120 is interfaced with the housing 210. The housing 210 is also shown as including a second end 214 at which the cable 130 is interfaced with the housing 210. The first end 212 of the housing 210 has a width or diameter that is relatively smaller than the width or diameter of the second end 214. Although the second end 214 is depicted as having a width or diameter that is approximately twice as large as the width or diameter of the first end 212, in other examples, the second end 214 has a width or diameter that is significantly larger, such as around 10 times larger, than the first end 212.

The HTS 120 is interfaced with the housing 210 through any suitable connection mechanism. As an example, the HTS 120 terminates in a female coupling device and the first end 212 of the housing 210 includes a male coupling device that securely mates with the female coupling device of the HTS 120. In addition, the cable 130 terminates in a female coupling device and the second end 214 of the housing 210 includes a male coupling device that securely mates with the female coupling device of the cable 130. In some examples, the interfaces between the HTS 120 and the cable 130 and the housing 210 create a hermetically sealed environment inside of the housing 210.

According to examples, the first end 212 of the housing 210 has a cross-sectional shape (into the plane of FIG. 2) that matches a cross-sectional shape (into the plane of FIG. 2) of the HTS 120 and/or the coupling device at the end of the HTS 120. Likewise, the second end 214 of the housing 210 has a cross-sectional shape (into the plane of FIG. 2) that matches a cross-sectional shape (into the plane of FIG. 2) of the cable 130 and/or the coupling device at the end of the cable 130. In some examples, the first end 212 has the same cross-sectional shape as the second end 214, while in other examples, the first end 212 has a different cross-sectional shape than the second end 214. In any of these examples, the first end 212 and the second end 214 have a circular cross-section, a rectangular cross-section, or another polygonal cross-section.

As also shown in FIG. 2, the HTS 120 includes a number of layers that enable electrical current to be delivered through an HTS conductor 200 in the HTS 120, while the temperature of the HTS conductor 200 is lowered to a temperature that is below a certain temperature at which the HTS conductor behaves as a superconductor. For instance, the temperature of the HTS conductor 200 is lowered to around the boiling point of liquid nitrogen, which is around 77K (−192.2° C.). The HTS conductor 200 is formed of a suitable material that behaves as a superconductor below the certain temperature, such as yttrium-barium-copper-oxide, lanthanum-barium-copper-oxide, or the like.

In some examples, a cooling liquid, such as liquid nitrogen, is used to reduce the temperature of the HTS conductor 200 to the temperature below the certain temperature. For instance, the HTS conductor 200 is a hollow tube and a cooling system 220 forces liquid nitrogen through the HTS conductor 200. In addition, the HTS conductor 200 may be housed within an outer tube 202 through which the liquid nitrogen is returned to the cooling system 220. In some examples, a thermal insulating layer (not shown) is provided between the HTS conductor 200 and the outer tube 202.

The HTS 120 is also depicted as including an electrical insulating layer 204 and multiple thermal insulating layers 206, 208. The electrical insulating layer 204 is formed of any suitable type of insulating material that prevents the flow of current into or out of the HTS conductor 200 through the electrical insulating layer 204. For instance, the electrical insulating layer 204 includes a high voltage insulating material such as a dielectric material. Likewise, the thermal insulating layer 206 is formed of any suitable type of insulating material that limits or prevents conduction of heat into or out of the HTS conductor 200. The thermal insulating layer 208 may be a multi-layer insulation in a vacuum. The HTS 120 further includes a sheath 209 to hold and protect the layers of the HTS 120.

As further shown in FIG. 2, the HTS conductor 200 is in electrical contact with components inside of the housing 210. For instance, the HTS conductor 200 extends through at least one first opening 216 in the first end 212 of the housing 210. Alternatively, a conductive wire (e.g., made of the same HTS conductor 200 material) is connected to the HTS conductor 200 through the at least one first opening 216. In some examples, the wall of the housing 210 at the first end 212 is insulated to reduce or limit the amount of thermal transfer between the HTS 120 and the interior of the housing 210.

The electrically conductive cable 130 connected to the second end 214 includes an electrical conductor 222 surrounded by a sheath 224. The electrical conductor 222 is formed of a material that conducts electricity with a relatively low level of loss at normal, e.g., room, temperatures. In addition, the electrical conductor 222 is electrically connected to components inside of the housing 210 through at least one second opening 218 in the second end 214 of the housing. The electrically conductive cable 130 is shown as including two conductors 222 for purposes of illustration. It should be understood that the electrically conductive cable 130 may include additional conductors 222 without departing from a scope of the present disclosure.

Reference is now made to FIG. 3A, which shows an enlarged view of the power coupling device 110 depicted in FIG. 2, in accordance with an embodiment of the present disclosure. Generally speaking, the power coupling device 110 receives an input current 300, for instance, from an HTS conductor 200 of an HTS 120 and mechanically transfers energy from the input current 300 to an output current 302, which is supplied to an electrically conductive cable 130. The power coupling device 110 couples the input current 300 to the output current 302 indirectly in that there is an air gap between the input current 300 and the output current 302, e.g., the energy does not flow through a common conductor. Instead, the power coupling device 110 includes a power coupling system 310 that mechanically transfers the input current 300 to the output current 302.

As shown in FIG. 3A, the power coupling system 310 includes a shaft 312 that is rotatably mounted within the housing 210. For instance, the shaft 312 is supported by one or more bearings 314 that are fixedly mounted to an interior of the housing 210. The bearings 314 generally support the shaft 312 such that the shaft 312 is prevented from movement other than rotational movement. According to examples, the bearings 314 enable the shaft 312 to rotate with minimal resistance.

The shaft 312 includes a motor side 316 having a motor assembly and a generator side 318 having a generator assembly, in which the generator assembly is thermally and electrically separated (or isolated) from the motor assembly. The motor assembly includes a set of motor magnets 320, e.g., permanent magnets 320, provided on the motor side 316 of the shaft 312, in which the motor magnets 320 are fixedly mounted on the shaft 312 such that movement of the motor magnets 320 causes the shaft 312 to rotate. The motor assembly also includes a set of motor coils 322 positioned near, e.g., adjacent to, the motor side 316 of the shaft 312. The motor coils 322 are also positioned to be in relatively close proximities to the motor magnets 320 as the motor magnets 320 rotate adjacent to the motor coils 322. For instance, at their closest distances, the motor coils 322 are within less than about 1 mm from the motor coils 322. According to examples, the set of motor coils 322 receive an electrical current (input current 300) from an HTS conductor 200 of an HTS 120. The flow of electrical current 300 into the motor coils 322 causes the motor magnets 320 to be repelled from (or attracted to) the motor coils 322, thus causing the shaft 312 to be rotated as denoted by the arrow 324.

In some examples, the motor coils 322 are formed of an HTS conductor material, for instance, the same material as the HTS conductor 200. In these examples, the motor coils 322 may be cooled through thermal contact with the HTS conductor 200. As a result, there may be minimal current loss from the HTS conductor 200 to the motor coils 322. In other examples, the motor coils 322 are formed of copper, aluminum, or the like.

The generator assembly includes a set of generator magnets 326, e.g., permanent magnets 326, provided on the generator side 318 of the shaft 312, in which the generator magnets 326 are fixedly mounted on the shaft 312 such that rotational movement of the shaft 312 causes the generator magnets 326 to rotate. The generator assembly also includes a set of generator coils 328 positioned near, e.g., adjacent to, the generator side 318 of the shaft 312. The generator coils 328 are also positioned to be in relatively close proximities to the generator magnets 326 as the generator magnets 326 rotate adjacent to the generator coils 328. For instance, at their closest distances, the generator coils 328 are within less than about 1 mm from the generator magnets 326. The generator coils 328 are formed of an electrically conductive material, such as copper, aluminum, or the like.

As the generator magnets 326 rotate with the shaft 312, an electrical current is generated in the generator coils 328 and the electrical current is conducted into the cable 130. In addition, the output current 302 is delivered through the cable 130 to a rack 142. As a result, the power coupling device 110 enables current supplied through an HTS conductor 200 of an HTS 120 to be delivered through an electrical conductor 222 of a cable 130 without the HTS conductor 200 contacting the electrical conductor 222. This separation may prevent the cold temperature at which the HTS conductor 200 is maintained from significantly affecting the temperature of the electrical conductor 222, which may prevent, for instance, the formation of condensation on the cable 130.

In some examples, the housing 210 includes an insulating layer 330 that reduces the transfer of heat between an interior and an exterior of the housing 210. The insulating layer 330 may also reduce the transfer of heat between the HTS conductor 200 and the electrical conductor 222. According to examples, a thermal insulator (not shown) is provided along the first end 212 of the housing 210 to reduce thermal transfer between the HTS 120 and an interior of the housing 210.

According to examples, the thermal insulation inside of the housing 210 is improved through the use of an inert gas inside of the housing 210. The inert gas may be, for instance, nitrogen. In other examples, the interior of the housing 210 is a vacuum chamber such that a vacuum space is formed after the HTS 120 and the electrically conductive cable 130 are interfaced with the housing 210. In these examples, the interior of the housing 210 is hermetically sealed. By having a vacuum environment inside of the housing 210, the thermal insulation inside of the housing 210 is improved and the amount of friction on the rotation of the shaft 312 may be minimized, which reduces losses in the generation of the output current 302.

According to examples, the shaft 312 is formed of a strong material that is able to withstand the large amounts of torque generated to rotate the shaft 312 and has a relatively low thermal conductivity. For instance, the shaft 312 is formed of a material such as stainless steel and has a relatively large diameter to enable the shaft 312 to withstand the large torque forces. The type of material and the diameter of the shaft 312 may be determined through testing, modeling, etc., and may vary for different types of applications. In other examples, the shaft 312 is formed of another material such as carbon steel, aluminum, titanium, ceramics, composite materials, or the like.

As the shaft 312 includes a relatively large mass, the shaft 312 obtains a relatively large moment of inertia as the shaft 312 rotates. As a result, if there is an interruption in the supply of the input current 300, the shaft 312 will continue to rotate for at least a short duration of time, which will also continue generation of the output current 302 for at least a short duration of time. In some instances, the shaft 312 continues to rotate to provide a rack 142 with uninterrupted power, thus reducing or eliminating downtime and/or a switch to an uninterrupted power supply (UPS).

FIG. 3B shows an enlarged view of the power coupling device 110 depicted in FIG. 2, in accordance with an embodiment of the present disclosure. The power coupling device 110 depicted in FIG. 3B includes each of the features of the power coupling device 110 depicted in FIG. 3A. However, the power coupling device 110 depicted in FIG. 3B includes a larger mass 340 at the center of the shaft 312 than at the motor side 316 and the generator side 318. The mass 340 is integrally formed with the shaft 312 or is attached to the shaft 312 through welding or mechanical fasteners. In addition, the mass 340 is formed of the same material as the shaft 312 or is formed of another type of material. In some examples, the larger mass 340 functions as a flywheel to conserve angular momentum and store rotational energy of the shaft 312.

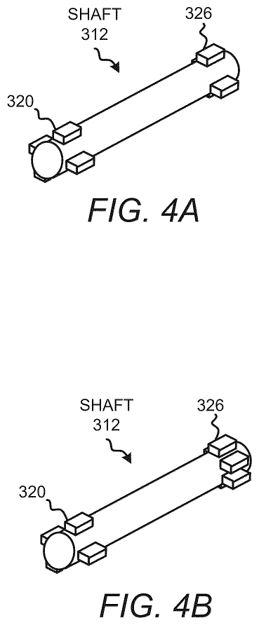

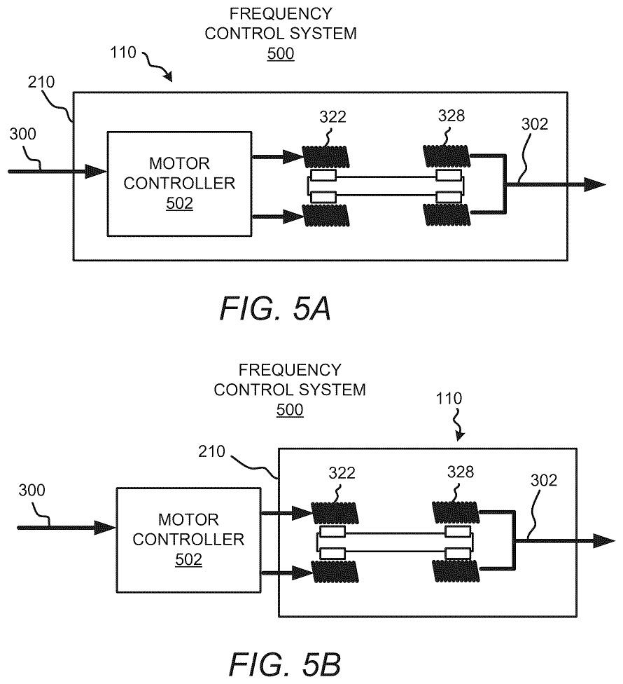

FIGS. 4A and 4B, respectively, show isometric side views of the shaft 312 shown in FIGS. 3A and 3B, in accordance with embodiments of the present disclosure. In the example shown in FIG. 4A, the shaft 312 includes the same number of generator magnets 326 (number of generator magnet poles 326) as motor magnets 320 (number of motor magnet poles 326). As a result, the frequency of the output current 302 is equivalent to the frequency of the input current 300 (discussed above with respect to FIG. 3A). In the example shown in FIG. 4B, the shaft 312 includes a different number of generator magnets 326 (or generator magnet poles 326) than the motor magnets 320 (or motor magnet poles 320). As a result, the frequency of the output current 302 differs from the frequency of the input current 300. In this regard, the frequency of the output current 302 may be controlled by varying the number of generator magnets 326 (or generator magnet poles 326) as compared with the number of motor magnets 320 (or motor magnet poles 320) provided on the shaft 312. For instance, the frequency of the output current 302 may be increased by increasing the number of generator magnets 326 (or generator magnet poles 326) as compared with the number of motor magnets 320 (or motor magnet poles 320). The increased output current 302 frequency may result in higher density power supply units and power conversion devices.

FIGS. 5A and 5B, respectively, show diagrams of an output current frequency control system 500, in accordance with embodiments of the present disclosure. As shown in FIGS. 5A and 5B, the frequency control system 500 includes a motor controller 502 (or a variable frequency drive) into which the input current 300 is directed. Particularly, the motor controller 502 receives the input current 300, which is at a first frequency, and adjusts the frequency of the input current 300 supplied to the motor coils 322. The frequency of the input current 300 applied to the motor coils 322 affects the rotational speed of the shaft 312, which varies the frequency of the output current 302 generated by the generator coils 328. The motor controller 502 controls the frequency of the output current 302, for instance, by controlling the frequency of the input current 300.

In some examples, and as shown in FIG. 5A, the motor controller 502 is housed within the housing 210 of the power coupling device 110. In these examples, the HTS 120 may be interfaced with the power coupling device 110 as shown in FIG. 2 and the motor controller 502 may be positioned to receive the input current 300 from the HTS conductor 200. In other examples, and as shown in FIG. 5B, the motor controller 502 is positioned outside of the housing 210. In these examples, the motor controller 502 may be interfaced with the HTS 120 directly and may include insulation to prevent the extremely cold temperature inside of the HTS 120 from affecting the operation of the motor controller 502. In addition, the motor controller 502 may be interfaced with the power coupling device 110 in manners similar to those disclosed above with respect to the interface between the HTS 120 and the power coupling device 110.

Although described specifically throughout the entirety of the instant disclosure, representative examples of the present disclosure have utility over a wide range of applications, and the above discussion is not intended and should not be construed to be limiting, but is offered as an illustrative discussion of aspects of the disclosure.

What has been described and illustrated herein is an example of the disclosure along with some of its variations. The terms, descriptions, and figures used herein are set forth by way of illustration only and are not meant as limitations. Many variations are possible within the scope of the disclosure, which is intended to be defined by the following claims—and their equivalents—in which all terms are meant in their broadest reasonable sense unless otherwise indicated.

What is claimed is:

1. A thermally separating power coupling device comprising:
a housing comprising:
a first end at which a high-temperature superconductor (HTS) is to be interfaced with the housing, the first end having a first opening through which an input current is to flow into the housing; and
a second end at which an electrically conductive cable to be interfaced with the housing, the second end having a second opening through which an output current is to flow out of the housing; and
a power coupling system housed within the housing, the power coupling system comprising:
a shaft rotatably mounted within the housing, the shaft having a motor side and a generator side;
a set of motor magnets attached to the motor side of the shaft;
a set of motor coils positioned near the set of motor magnets, the set of motor coils to receive an electrical current from the HTS, wherein the received electrical current causes the set of motor magnets to rotate the shaft;
a set of generator magnets attached to the generator side of the shaft; and
a set of generator coils positioned near the set of generator magnets, the set of generator coils to output an electrical current to the electrically conductive cable when the shaft rotates.

2. The thermally separating power coupling device of claim 1, further comprising:
at least one shaft bearing positioned inside the housing, the at least one shaft bearing supporting the shaft while enabling the shaft to rotate within the housing.

3. The thermally separating power coupling device of claim 1, further comprising:
an insulating layer provided within the housing to reduce thermal transfer between an interior and an exterior of the housing.

4. The thermally separating power coupling device of claim 1, further comprising:
an insulator provided along the first end of the housing to reduce thermal transfer between the HTS and an interior of the housing.

5. The thermally separating power coupling device of claim 1, further comprising:
an inert gas inside the housing, wherein the housing is hermetically sealed after the HTS and the electrically conductive cable are interfaced with the housing.

6. The thermally separating power coupling device of claim 1, wherein the housing comprises a vacuum chamber.

7. The thermally separating power coupling device of claim 1, wherein the first end and the second end are different in cross-sectional size from each other.

8. The thermally separating power coupling device of claim 1, wherein the set of motor coils is formed of HTS conductor material.

9. The thermally separating power coupling device of claim 1, wherein a center of the shaft has a greater mass than the motor side and the generator side of the shaft.

10. The thermally separating power coupling device of claim 1, wherein a number of magnet poles in the set of motor magnets differs from a number of magnet poles in the set of generator magnets to cause a frequency of the electrical current being inputted through the motor coils to differ from a frequency of the electrical current being outputted through the generator coils.

11. The thermally separating power coupling device of claim 1, further comprising:
a motor controller to control a frequency of the electrical current being outputted through the generator coils by controlling a rotational speed of the shaft.

12. A power connection system comprising:
a high-temperature superconductor (HTS) to receive a current from a power source, the HTS having an HTS conductor;
an electrically conductive cable to supply an output current to at least one electronic equipment, the electrically conductive cable having an electrical conductor; and
a power coupling device having:
a first end interfaced with the HTS;
a second end interfaced with the HTS; and
a power coupling system comprising:
a rotatably mounted shaft having a motor side and a generator side;
wherein an input current from the HTS conductor drives a motor assembly to rotate the shaft and wherein rotation of the shaft causes a generator assembly to generate the output current, and wherein the generator assembly is thermally and electrically isolated from the motor assembly.

13. The power connection system of claim 12, wherein:
the motor assembly comprises:
a set of motor magnets attached to the motor side of the shaft; and
a set of motor coils positioned near the set of motor magnets, the set of motor coils to receive the input current from the HTS conductor; and the generator assembly comprises:
a set of generator magnets attached to the generator side of the shaft; and
a set of generator coils positioned near the set of generator magnets, the set of generator coils to output the output current to the electrical conductor.

14. The power connection system of claim 12, further comprising:
an insulator provided along the first end to thermally insulate an interior of the power coupling device from the HTS.

15. The power connection system of claim 12, wherein an interior of the power coupling device is a vacuum or includes an inert gas.

16. The power connection system of claim 12, wherein the power coupling system causes the output current to have a frequency that differs from a frequency of the input current.

17. A power coupling device comprising:
a housing to couple a high-temperature semiconductor (HTS) with an electrically conductive cable, the HTS having an HTS conductor and the electrically conductive cable having an electrical conductor; and
a power coupling system housed within the housing, the power coupling system comprising:
a rotatably mounted shaft having a motor side and a generator side;
a motor assembly on the motor side; and
a generator assembly on the generator side,
wherein an input current from the HTS conductor drives the motor assembly to rotate the shaft and wherein rotation of the shaft causes the generator assembly to generate an output current, and wherein generator assembly is thermally and electrically isolated from the motor assembly.

18. The power coupling device of claim 17, wherein:
the motor assembly comprises:
a set of motor magnets attached to the motor side of the shaft; and
a set of motor coils positioned adjacent to the set of motor magnets, the set of motor coils to receive the input current from the HTS conductor; and
the generator assembly comprises:
a set of generator magnets attached to the generator side of the shaft; and
a set of generator coils positioned adjacent to the set of generator magnets, the set of generator coils to output the output current to the electrical conductor.

19. The power coupling device of claim 17, wherein an interior of the housing is a vacuum or includes an inert gas.

20. The power coupling device of claim 17, wherein the power coupling system is to cause the output current to have a frequency that differs from a frequency of the input current.
